(19) United States
(12) Patent Application Publication
(10) Pub. No.: US 2012/0273637 A1
(43) Pub. Date: Nov. 1, 2012

(54) MOUNTING APPARATUS

(76) Inventor: Ming Hua Huang, Kaohsiung City (TW)

(21) Appl. No.: 13/094,847

(22) Filed: Apr. 27, 2011

(51) Int. Cl. H05K 7/00

(52) U.S. Cl. 248/291.1

(57) ABSTRACT

The mounting apparatus comprises a holding seat, a supporting member, and a base. The holding seat is used for holding flat electronic devices in place to prevent them from detachment to cause damages. The supporting member is pivotably connected to the rear of the holding seat such that the angle between the supporting member and the holding seat can be adjusted. The supporting member is provided with a first pivoting portion. The base is provided with a second pivoting portion and a third pivoting portion for being pivotably connected with the first pivoting portion of the supporting member such that the angle between the supporting member and the base can be adjusted smoothly. The mounting apparatus can hold flat electronic devices conveniently and provide functions of apparatus folding and fine angle adjustment with high load capacity.

### TECHNICAL FIELD OF THE INVENTION

The present invention relates to a mounting apparatus and, more particularly, to a structure that can hold flat electronic devices such as flat computers, electronic books and personal digital assistants in place, containing functions of apparatus folding and fine angle adjustment with high load capacity.

### DESCRIPTION OF THE PRIOR ART

Due to the rapid progress of information technology, various new kinds of electronic information products have been introduced, in which smart products are the trend. The flat electronic products, such as flat computers, electronic books and personal digital assistants, are light in weight and thin in dimension, however, they require a user's hand to hold them in place and this bring some inconvenience in operation. Thus, there is a need for providing a mounting apparatus that can help users to hold them in place so as to facilitate an operation.

### SUMMARY OF THE INVENTION

The primary object of the present invention is to provide a mounting apparatus that can hold flat electronic devices in place and provide functions of apparatus folding and fine angle adjustment with high load capacity.

According to one aspect of the invention, the apparatus includes a holding seat, a supporting member and a base; wherein the holding seat is used for holding flat electronic devices in place to prevent them from detachment to cause damages, the supporting member is pivotably connected to the rear of the holding seat such that the angle between the supporting member and the holding seat can be adjusted, the supporting member is provided with a first pivoting portion, the base is provided with a second pivoting portion and a third pivoting portion for being pivotably connected with the first pivoting portion of the supporting member such that the angle between the supporting member and the base can be adjusted smoothly; whereby the mounting apparatus can facilitate to hold flat electronic devices in place and provide functions of apparatus folding and fine angle adjustment with high load capacity.

According to another aspect of the invention, the apparatus also includes a locking element, which is comprised of a disc and a lug extended therefrom, the disc defining a central rounded hole to rotatably fit to the limiting rod of the rear cover portion and being provided with more than one protrusions spaced around the central rounded hole, the rear cover portion being provided with more than one protrusions spaced around the limiting rod corresponding to the protrusions of the disc, the lug being extended out of a buttom of the front and rear cover portions; whereby, when the locking element is rotated via the lug, the locking element can be move forward to urge against the lower clamping plate via the protrusions of the rear cover portion in contact with the protrusions of the locking element to further secure the lower clamping plate such that flat electronic devices can be more firmly held in the holding seat.

According to another aspect of the invention, the apparatus also includes annular projection provided at one end of the third pivoting portion and adjacent to the first pivoting portion for mating with a recess of the first cylindrical hole of the first pivoting portion such that the first, second and third cylindrical holes can be coaxially aligned to facilitate axial movement of the shaft.

Other objects, advantages, and novel features of the present invention will become more apparent from the following detailed description when taken in conjunction with the accompanying drawings.

### BRIEF DESCRIPTION OF THE DRAWINGS

FIG. 1 is a 3-dimensional view of the present invention.

FIG. 2 is an exploded view of the present invention.

FIG. 3 is a front plan view of the present invention showing a structure of the holding seat.

FIG. 4 is a front plan view of the present invention, schematically showing a structure of the holding seat and a flat electronic device placed in the holding seat via moving the lower clamping plate downwardly or upwardly to drive the left and right clamping plates to move inwardly or outwardly of the holding seat so as to grip or release the flat electronic device.

FIG. 5 is a side view of the present invention.

FIG. 6 is a sectional view taken along I-I in FIG. 5, schematically showing the external toothed portion of the shaft engaged with the first and second internal toothed portions.

FIG. 7 is a sectional view of the present invention, schematically showing the external toothed portion of the shaft disengaged from the second internal toothed portion.

FIG. 8 is a schematic view of the present invention, which shows the first pivoting portion and the supporting member being rotated to various angles.

FIG. 9 is a side view of the present invention, which shows a folded condition of the mounting apparatus.

FIG. 10 is a partially enlarged exploded view of the present invention.

FIG. 11 is a sectional view of the present invention, schematically showing the locking element in the urging condition.

FIG. 11A is an enlarged view of a portion of FIG. 11.

### DETAILED DESCRIPTION OF THE PREFERRED EMBODIMENTS

The technical means and the structure of the present invention will be more easily understood by reference to the following detailed description, when taken in conjunction with the accompanying drawings.

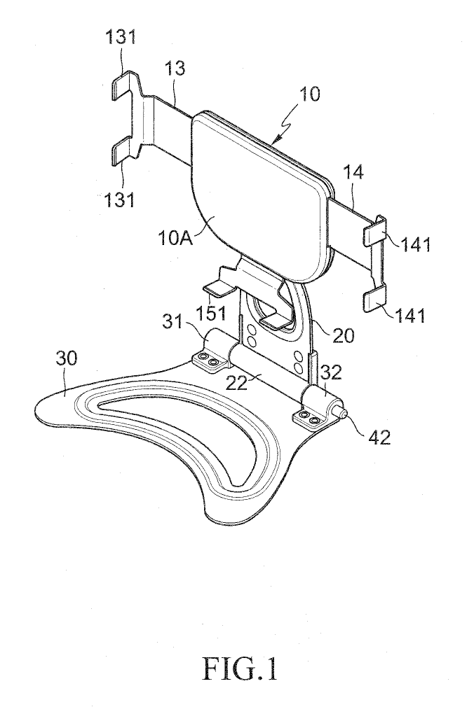

As shown in FIGS. 1, 2, 3 and 4, an embodiment of the present invention generally comprises a holding seat 10, a supporting member 20, and a base 30.

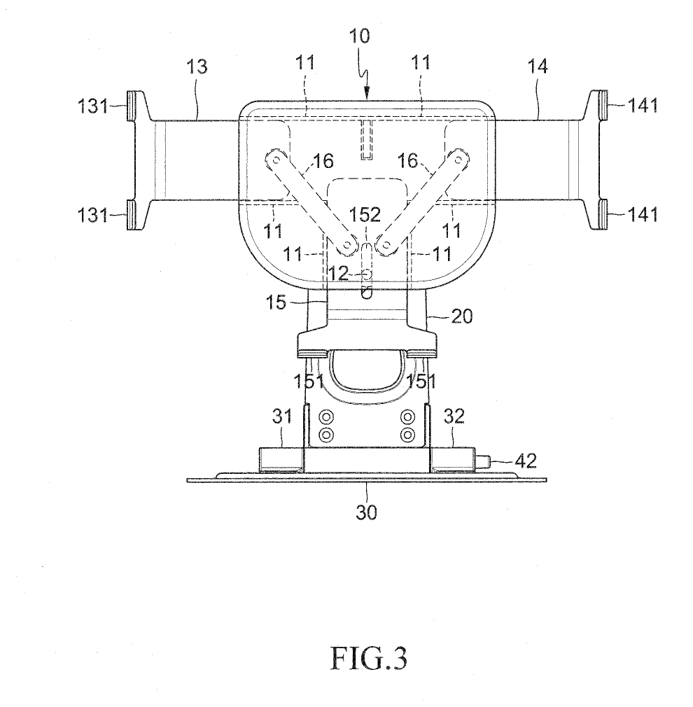

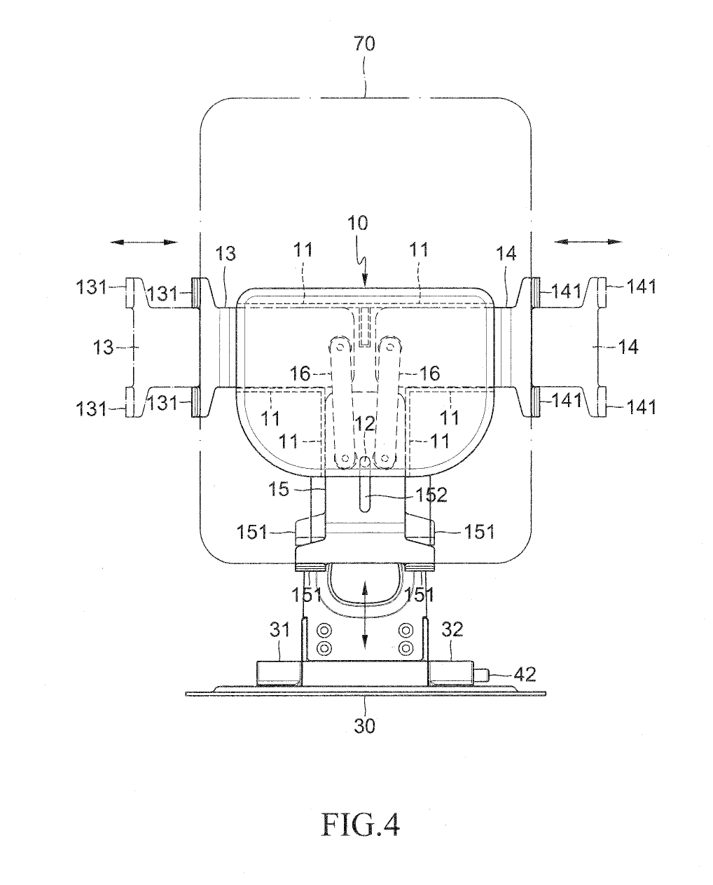

The holding seat 10 is comprised of a front cover portion 10A and a rear cover portion 10B, which are combined to define a hollow space therein. The rear cover 10B is provided with a plurality of guiding walls 11 and a limiting rod 12. A left clamping plate 13, a right clamping plate 14 and a lower clamping plate 15 are mounted in the hollow space of the holding seat 10, each plate extending out of the holding seat 10 and having a finger portion 131, 141 or 151 at a distal end outside of the holding seat 10 such that each clamping plate can be guided by the respective guiding walls 11 to move inwardly or outwardly of the holding seat 10. The lower clamping plate 15 defines a limiting slot 152 to be slidably inserted with a limiting rod 12 of the rear cover portion 10B such that the lower clamping plate 15 can be moved within a limited range. Furthermore, the left clamping plate 13 and the right clamping plate 14 are each connected with the lower clamping plate 15 via a link 16 such that, when the lower clamping plate 15 is moved downwardly, the left and right clamping plates 13, 14 can be driven to move inwardly of the holding seat 10 (see FIG. 4), when the lower clamping plate 15 is move upwardly, the left and right clamping plates 13, 14 can be driven to move outwardly of the holding seat 10 (see FIG. 3).

The supporting member 20 is pivotably connected to the rear cover portion 10B of the holding seat 10 via a pivoting joint 21 such that the holding seat 10 can be pivoted about the pivoting joint 21 to change the angle between the holding seat 10 and the supporting member 20. The supporting member 20 is further provided with a first pivoting portion 22, which defines a first cylindrical hole 23 at one end thereof and an end pin 25 at another end thereof. A first internal toothed portion 24 is provided in the first cylindrical hole 23 of the first pivoting portion 22.

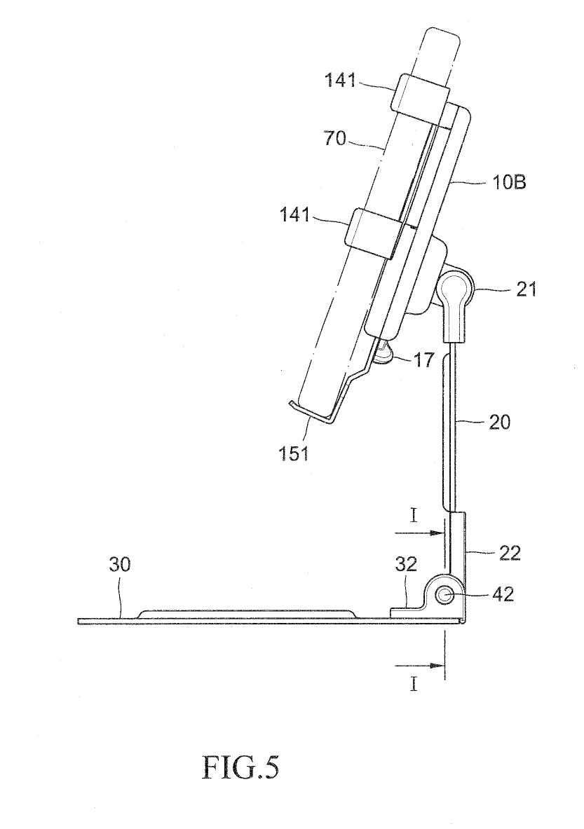

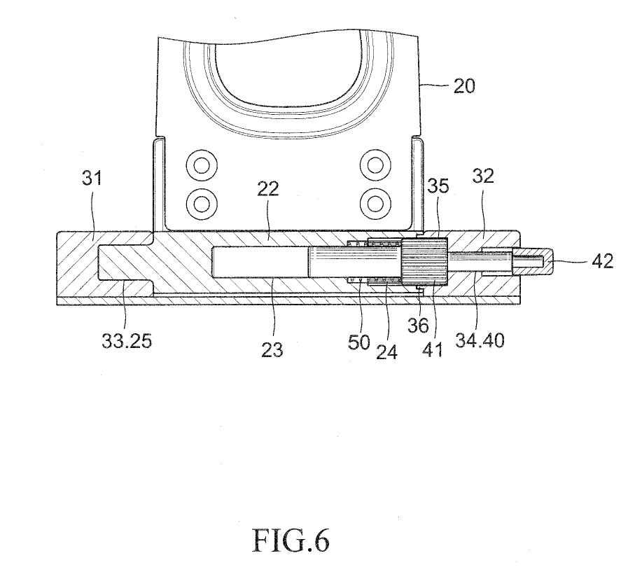

Referring to FIG. 5 and FIG. 6, the base 30 is pivotably connected with the supporting member 20. The base 30 has a second pivoting portion 31 and a third pivoting portion 32, the first pivoting portion 22 of the supporting member 20 being mounted between the second pivoting portion 31 and the third pivoting portion 32, the second pivoting portion 31 being provided with a second cylindrical hole 33, the third pivoting portion 32 being provided with a third cylindrical hole 34. The first, second and third pivoting portions are connected such that the end pin 25 of the first pivoting portion 22 is rotatably inserted in the second cylindrical hole 33 of the second pivoting portion 31 such that the first, second and third cylindrical holes 23, 33, 34 are coaxially aligned, the first pivoting portion 22 can be rotated about the second pivoting portion 31. A second internal toothed portion 35 is provided in the third cylindrical hole 34 of the third pivoting portion 32 and adjacent to the first internal toothed portion 24 in the first cylindrical hole 23 of the first pivoting portion 22.

As mentioned above, the first pivoting portion 22 of the supporting member 20 is connected with the second and third pivoting portions of the base 30 such that the holes 23, 34 of the first and third pivoting portions 22, 32 are sequentially inserted with a spring 50 and a shaft 40, the shaft 40 being able to axially moved between the first cylindrical hole 23 of the first pivoting portion 22 and the third cylindrical hole 34 of the third pivoting portion 32, the shaft 40 being provided with an external toothed portion 41 capable of engaging with the first and second internal toothed portions 24, 35, the shaft 40 being fitted with a button cap 42 at one end extending out of the third pivoting portion 32, the spring 50 being mounted on another end of the shaft 40 to exert an outward force to the shaft 40 such that the external toothed portion 41 of the shaft can be simultaneously engaged with the first and second internal toothed portions 24, 35 in normal condition.

According to the present invention, when in use, a flat electronic device 70 can be placed on the holding seat 10. Then, the left and right clamping plates 13, 14 can be moved inwardly of the holding seat 10 by moving the lower clamping plate 15 downwardly, such that the flat electronic device 70 can be gripped by the respective finger portions 131, 141 of the left and right clamping plates 13, 14 so as to hold the device 70 in place, as shown in FIG. 4. When the flat electronic device 70 is not in use, the lower clamping plate 15 can be moved upwardly to enable the left and right clamping plates 13, 14 to move outwardly of the holding seat 10 so as to release the device 70.

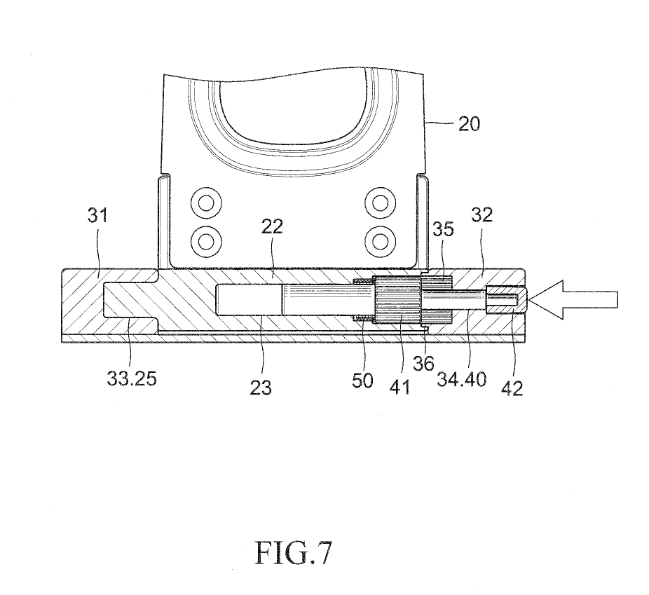

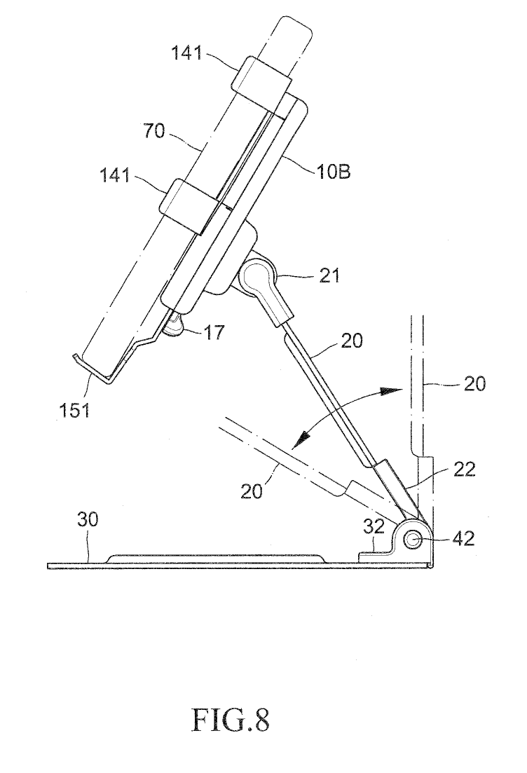

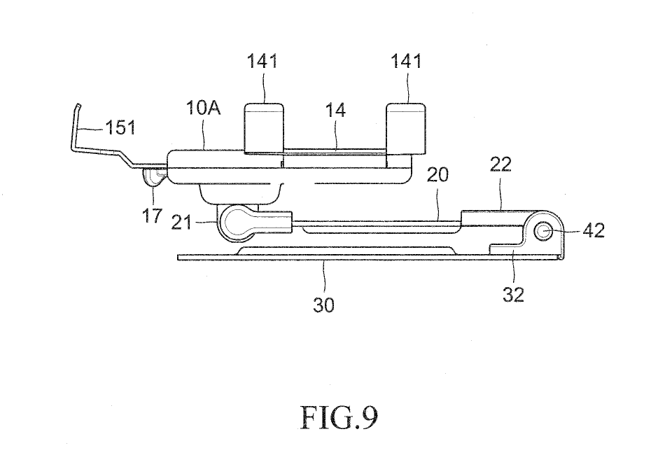

As shown in FIG. 5 and FIG. 6, in normal condition, the external toothed portion 41 is simultaneously engaged with the first and the second internal toothed portions 24, 35 such that the first pivoting portion 22 can be affixed to the third pivoting portion 32 at a predetermined angle such that the supporting member 20 and the base 30 can be each kept at a fixed position. When a different angle between the supporting member 20 and the base 30 is required, the user can press the button cover 42 to enable the shaft 40 to move inwardly of the first pivoting portion 22 (see FIG. 7) and thus to disengage the external toothed portion 41 from the second internal toothed portion 35 of the third pivoting portion 32 such that the first pivoting portion 22 can be rotated about the second pivoting portion 31 so as to rotate the supporting member 20 to a desired angle (see FIG. 8). After releasing the button cap 42, the shaft 40 can be pushed back by the spring 50 to return to its original position such that the external toothed portion 41 can be again engaged with the internal toothed portion 35 (see FIG. 6) such that the first pivoting portion 22 is again affixed to the third pivoting portion 32 such that the supporting member 20 and the base 30 are each kept at a different position after following the movement of the first and third pivoting portions 22, 32 to thereby facilitate the operation of holding a flat electronic device 70 at a desired angle. When the present invention is not in use, the button cover 42 can be pressed again to move the shaft 40 inwardly of the first cylindrical hole 23 so as to disengage the external toothed portion 41 of the shaft 40 from the second internal toothed portion 35 of the third pivoting portion 32 such that the supporting member 20 can be folded against the base 30 (see FIG. 9). Also, the holding seat 10 can be rotated clockwise to fold the holding seat 10 against the supporting member 20 to obtain a compact form of device to facilitate the storage and the portability.

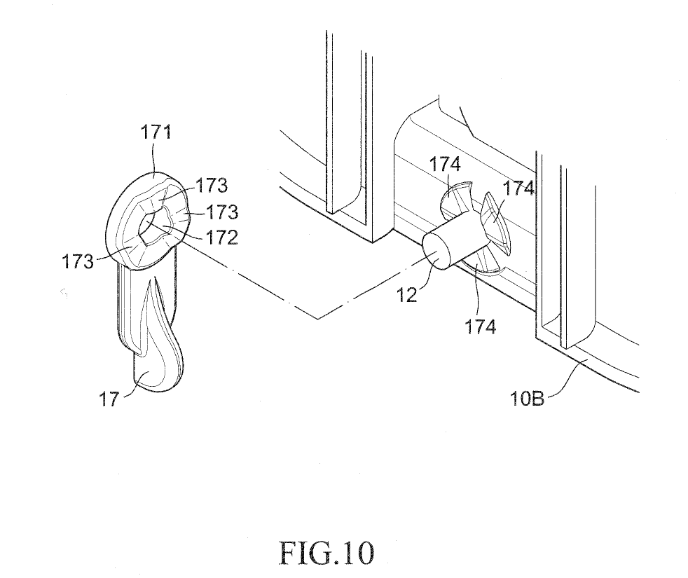

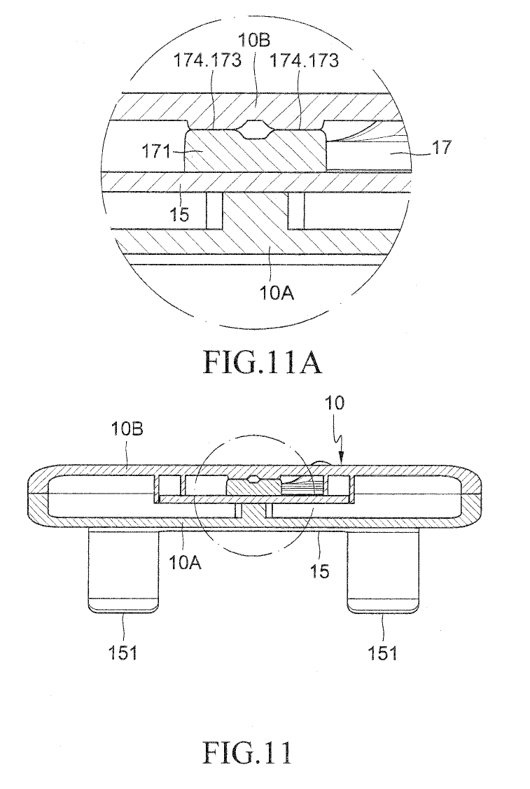

As shown in FIG. 10, the present invention further comprises a locking element 17, which is comprised of a disc 171 and a lug projecting from the disc 171. The disc 171 defines a central rounded hole 172 to rotatably fit to the limiting rod 12 of the rear cover portion 10B. The disc 171 is provided with more than one protrusions 172 spaced around the central rounded hole 172. Similarly, the rear cover portion 10B is provided with more than one protrusions 174 spaced around the limiting rod 12 corresponding to the protrusions 173 of the disc 171. The lug projecting from the disc 171 is extended out of a buttom of the front and rear cover portions 10A, 10B. As shown in FIGS. 11 and 11A, the disc 171 can be moved forwardly to urge against the lower clamping plate 15 via the protrusions 174 of the rear cover in contact with the protrusions 173 of disc to further secure the lower clamping plate 15 such that a flat electronic device 70 can be more firmly held on the holding seat 10.

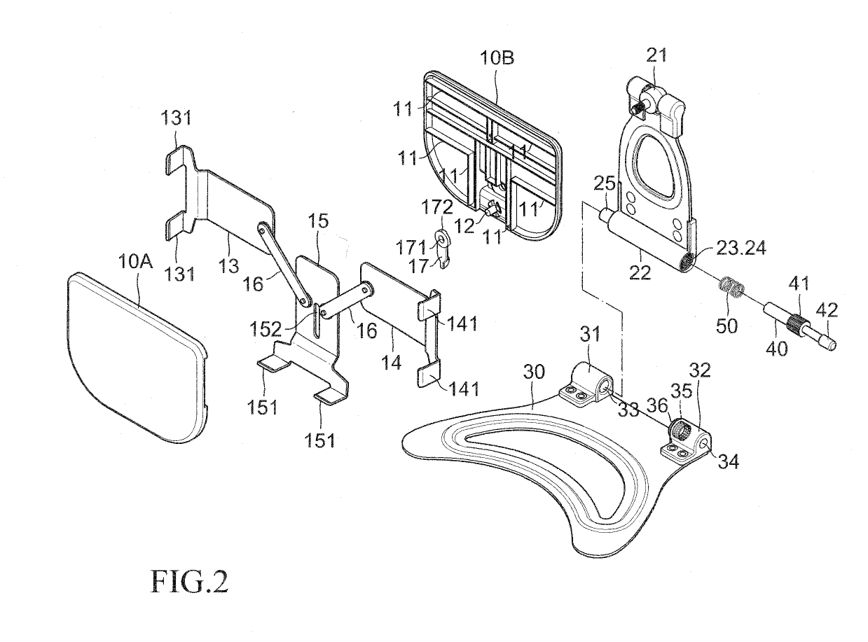

Furthermore, as shown in FIGS. 2, 5 and 6, according to the embodiment of the present invention, the third pivoting portion 32 is provided with an annular projection 36 at one end thereof and adjacent to the first pivoting portion 22 for mating with a recess of the first cylindrical hole 23 of the first pivoting portion 22 such that the first, second and third cylindrical holes 23, 33, 34 can be coaxially aligned to facilitate axial movement of the shaft 40.

Accordingly, the present invention can hold electronic devices of various sizes on the holding seat 10 through the left, right and lower clamping plates 13, 14, 15. Furthermore, in addition to the fact that the supporting member 20 can be rotated relative to the base 30 to facilitate storage and protability, the external toothed portion 41 can releasably engage with the first and third internal toothed portions 24, 35 so as to smoothly adjust an ideal angle between the supporting member 20 and the base 30, and increase the load capacity to prevent the supporting member 20 from detaching the base 30, and thus avoid damages of the flat electronic devices.

In light of the foregoing, it is believed that the mounting apparatus of the present invention can be used for holding flat electronic devices of various sizes conveniently, with fine adjustment of angle and high capacity of load.

Although the present invention has been described with a certain degree of particularity, it is understood that the present disclosure is made by way of example only and the combination and arrangement of parts may be resorted to without departing from the spirit and scope of the invention hereinafter claimed.

I claim:

1. A mounting apparatus comprising a holding seat, a supporting member and a base; wherein:
said holding seat is comprised of a front cover portion and a rear cover portion, which are combined to define a hollow space therein, said rear cover being provided with a plurality of guiding walls and a limiting rod, a left clamping plate, a right clamping plate and a lower clamping plate are mounted in said hollow space of said holding seat, each plate having a finger portion at a distal end thereof outside of said holding seat such that each clamping plate can be guided by the respective guiding walls to move inwardly or outwardly of said holding seat, said lower clamping plate defining a limiting slot to be slidably inserted with said limiting rod of said rear cover portion such that said lower clamping plate can be moved within a limited range, said left clamping plate and said right clamping plate are each connected with said lower clamping plate via a link such that, when said lower clamping plate is moved downwardly, said left and right clamping plates can be driven to move inwardly of said holding seat, when said lower clamping plate is move upwardly, said left and right clamping plates can be driven to move outwardly of said holding seat;
said supporting member, being pivotably connected to said rear cover portion of said holding seat via a pivoting joint such that said holding seat can be pivoted about said pivoting joint, is provided with a first pivoting portion defining a first cylindrical hole at one end thereof and an end pin at another end thereof, a first internal toothed portion being provided in said first cylindrical hole of said first pivoting portion; and
said base, being pivotably connected with said supporting member, has a second pivoting portion and a third pivoting portion, said first pivoting portion being mounted between said second pivoting portion and said third pivoting portion, said second pivoting portion being provided with a second cylindrical hole, said third pivoting portion being provided with a third cylindrical hole, said first, second and third pivoting portions are connected such that said end pin of said first pivoting portion is rotatably inserted in said second cylindrical hole of said second pivoting portion such that said first, second and third cylindrical hole are coaxially aligned, said first pivoting portion can be rotated about said second pivoting portion, a second internal toothed portion being provided in said third cylindrical hole of said third pivoting portion and adjacent to said first internal toothed portion of said first cylindrical hole of said first pivoting portion; further wherein:
said first pivoting portion of said supporting member is connected with said second and third pivoting portions of said base such that said holes of said first and third pivoting portions are sequentially inserted with a spring and a shaft, said shaft being able to axially moved between said first cylindrical hole and said third cylindrical hole, said shaft being provided with an external toothed portion capable of engaging with said first and second internal toothed portions, said shaft being fitted with a button cap at one end thereof to extend out of said third pivoting portion, said spring being mounted on another end of said shaft to exert an outward force to said shaft such that said external toothed portion of said shaft can be engaged with said first and second internal toothed portions in normal condition;
whereby, the mounting apparatus can hold flat electronic devices in place and further contain functions of apparatus folding and fine angle adjustment with high load capacity.

2. The mounting apparatus of claim 1, further comprising a locking element, which is comprised of a disc and a lug extended therefrom, said disc defining a central rounded hole to rotatably fit to said Emitting rod of said rear cover portion and being provided with more than one protrusions spaced around said central rounded hole, said rear cover portion being provided with more than one protrusions spaced around said limiting rod corresponding to said protrusions of said disc, said lug being extended out of a buttom of said front and rear cover portions; whereby, when said locking element is rotated via said lug, said locking element can be moved forward to urge against said lower clamping plate via said protrusions of said rear cover in contact with said protrusions of said locking elements to further secure said lower clamping plate such that a flat electronic device can be firmly held on said holding seat.

3. The mounting apparatus of claim 1, wherein said third pivoting portion is provided with an annular projection at one end thereof and adjacent to said first pivoting portion for mating with a recess of first cylindrical hole of said first pivoting portion such that said first, second and third cylindrical holes can be coaxially aligned to facilitate axial movement of said shaft.
